(19) United States
(12) Patent Application Publication
(10) Pub. No.: US 2024/0387492 A1
(43) Pub. Date: Nov. 21, 2024

(54) DISPLAY DEVICE

(71) Applicant: LG ELECTRONICS INC., Seoul (KR)

(72) Inventors: Dohan KIM, Seoul (KR); Wonseok CHOI, Seoul (KR); Wonjae CHANG, Seoul (KR); Jinsung KIM, Seoul (KR)

(73) Assignee: LG ELECTRONICS INC., Seoul (KR)

(21) Appl. No.: 18/692,576

(22) PCT Filed: Sep. 17, 2021
(86) PCT No.: PCT/KR2021/012900

§ 371 Date: Mar. 15, 2024

(51) Int. Cl. H01L 25/16; G09G 3/32; H01L 23/00; H01L 33/62

(52) U.S. Cl. CPC H01L 25/167; H01L 24/29; H01L 24/32; H01L 24/83; H01L 33/62; G09G 3/32; G09G 2300/0842; H01L 2224/29007; H01L 2224/29082; H01L 2224/32237; H01L 2224/83085; H01L 2224/83887; H01L 2224/8391

(57) ABSTRACT

The display device can include a substrate; a barrier rib disposed on the substrate and having an assembly hole; a semiconductor light emitting device in the assembly hole; and an adhesive part between the substrate and the semiconductor light emitting device within the assembly hole. The adhesive part can include adhesive particles in contact with each other.

### BACKGROUND OF THE DISCLOSURE

### Field

The embodiment relates to a display device.

### Discussion of the Related Art

A display device displays high-definition image using self-emissive device such as a light emitting diode as a light source for a pixel. The light emitting diode exhibits excellent durability even under harsh environmental conditions and is capable of long lifespan and high luminance, so that that that it is attracting attention as a light source for next-generation display devices.

Recently, research is in progress to manufacture ultra-small light emitting diodes using highly a material having reliable inorganic crystal structure and dispose them on the panel of a display device (hereinafter referred to as “display panel”) to use them as a light source for a next-generation pixel.

This display device is expanding beyond a flat display into various forms such as a flexible display, a foldable display, a stretchable display, and a rollable display.

In order to realize high resolution, the size of the pixel is gradually becoming smaller, and numerous light emitting devices must be aligned in the smaller pixel, so that that research on the manufacture of ultra-small light emitting diodes as small as micro- or nano-scale is actively taking place.

Typically, a display panel contains millions to tens of millions of pixels. Accordingly, because it is very difficult to align at least one or more light emitting device in each of tens of millions of small pixels, various studies on ways to align light emitting devices in the display panel are being actively conducted recently.

As the size of light emitting devices becomes smaller, transferring these light emitting devices onto a substrate is becoming a very important problem to solve. Transfer technologies that have been recently developed include a pick and place process, a laser lift-off method, a self-assembly method, etc. In particular, the self-assembly method that transfers light emitting devices onto a substrate using a magnetic body (or magnet) has recently been in the spotlight.

In the self-assembly method, numerous light emitting devices are dropped into a bath containing a fluid, and as the magnetic body moves, the light emitting devices dropped into the fluid are moved to each pixel on the substrate, and the light emitting devices are aligned at each pixel. Therefore, the self-assembly method is attracting attention as a next-generation transfer method because it can quickly and accurately transfer numerous light emitting devices onto a substrate.

Meanwhile, the light emitting devices aligned in the pixels on the substrate undergo post-processes such as a bonding process and a wiring connection process to manufacture a display device.

During this post-processing process, the light emitting devices aligned to the pixels on the substrate must be fixed so that they do not come off.

In the related art, a method of disposing a photoresist film around a light emitting device and fixing the light emitting device using the photoresist film was attempted. The photoresist film is formed by spin coating, for which the substrate is rotated. In this instance, there is a problem that the light emitting device is separated or lifted off the substrate due to rotation of the substrate, resulting in bonding defects or wiring connection defects.

Additionally, a method of forming an adhesive pattern on a pixel on a substrate and fixing a light emitting device using this adhesive pattern has been attempted in the related art. However, because the size of the pixel is small, it is difficult to form an adhesive pattern in a sub-pixel basis. There is a problem that due to misalignment, the adhesive pattern is not formed within the pixel but is formed in the area between pixels, resulting in additional defects. In particular, in light of the trend of increasingly demanding ultra-high resolution, it is very difficult to form an adhesive pattern in a sub-pixel basis.

### SUMMARY OF THE DISCLOSURE

An object of the embodiment is to solve the foregoing and other problems.

Another object of the embodiment is to provide a display device capable of forming an adhesive part in sub-pixel units through particle-level control.

Another object of the embodiment is to provide a display device that can reduce manufacturing costs and improve productivity by using dielectrophoretic forces not only for assembling a semiconductor light emitting device but also for forming an adhesive part.

Another object of the embodiment is to provide a display device that can improve yield and lighting yield.

Another object of the embodiment is to provide a display device that can improve product reliability by strengthening fixation.

The technical problems of the embodiments are not limited to those described in this item and include those that can be understood through the description of the invention.

According to one aspect of the embodiment to achieve the above or other objects, a display device, comprising: a substrate; a barrier rib disposed on the substrate and having an assembly hole; a semiconductor light emitting device in the assembly hole; and an adhesive part between the substrate and the semiconductor light emitting device within the assembly hole, wherein the adhesive part comprises adhesive particles in contact with each other.

The adhesive part can comprise a first adhesive layer comprising a plurality of first adhesive particles, and a second adhesive layer stacked on the first adhesive layer and comprising a plurality of second adhesive particles.

The display device can comprise a first assembling wiring on the substrate; a second assembling wiring on the substrate; and a first insulating layer on the first assembling wiring and the second assembling wiring, wherein the adhesive part can be disposed between the first insulating layer and the semiconductor light emitting device within the assembly hole.

The display device can comprise a connection electrode within the assembly hole; a second insulating layer on the barrier rib and the semiconductor light emitting device; and an electrode wiring configured to be connected to the semiconductor light emitting device through the second insulating layer, wherein the connection electrode can connect at least one of the first assembling wiring and the second assembling wiring to a side portion of the semiconductor light emitting device.

According to another aspect of the embodiment, a method of manufacturing a display device comprising a substrate, first and second assembling wirings on the substrate, and an assembly hole on the substrate, comprising: providing a chamber containing a fluid in which adhesive particles are diluted; forming an adhesive part in the assembly hole by using the adhesive particles by applying a first voltage having a first frequency to the first assembling wiring and the second assembling wiring; and assembling a semiconductor light emitting device into the assembly hole by applying a second voltage having a second frequency to the first assembling wiring and the second assembling wiring.

The method of manufacturing a display device can comprise curing the adhesive part by irradiating ultraviolet light; and cleaning the substrate.

In the embodiment, the adhesive part 380 can be formed in sub-pixel units through particle-level control. As high resolution or ultra-high resolution increases, the size of the sub-pixel becomes smaller, making it difficult to form the adhesive part 380. However, the adhesive part 380 can be formed within the assembly hole 345 by individually controlling adhesive particles 381 and 382 using dielectrophoretic force.

Specifically, as shown in FIG. 12, a first voltage V1 having a first frequency f1 can be applied to a first assembling wiring 321 and a second assembling wiring 322. A first dielectrophoretic force can be formed between the first assembling wiring 321 and the second assembling wiring 322 by the first voltage V1 having the first frequency f1, and the adhesive particles 381 and 382 near the assembly hole 345 or far away from the assembly hole 345 can be pulled into the assembly hole 345 by this first dielectrophoretic force, so that the adhesive part 380 can be formed by stacking on the bottom part of the assembly hole 345, that is, the upper surface of a first insulating layer 330.

Thereafter, as shown in FIG. 13, a second voltage V2 having a second frequency f2 can be applied to the first assembling wiring 321 and the second assembling wiring 322. A second dielectrophoretic force can be formed between the first assembling wiring 321 and the second assembling wiring 322 by the second voltage V2 having the second frequency f2, and the semiconductor light emitting device 150 located near the assembly hole 345 can be assembled into the assembly hole 345 by the second dielectrophoretic force.

Afterwards, at least one of the drying process (FIG. 15), the light curing process (FIG. 16), and the cleaning process (FIG. 17) can be performed, thereby strengthening the adhesive properties of the adhesive part 380, so that the semiconductor light emitting device 150 can be firmly fixed to the substrate 310, that is, the first insulating layer 330.

Therefore, even if post-processes, such as the formation process of a connection electrode 350, the formation process of a second insulating layer 360, and the formation process of a electrode wiring 372, are performed, the semiconductor light emitting device 150 can be firmly fixed to the first insulating layer 330 by the adhesive part 380 to prevent the semiconductor light emitting device 150 from being separated. Accordingly, the yield can be improved by blocking the separation of the semiconductor light emitting devices 150 assembled on the substrate 310 or reducing the number of separations, thereby reducing the lighting yield of the semiconductor light emitting devices 150 disposed in a plurality of sub-pixels.

In addition, in the embodiment, the formation of the adhesive part 380, the assembly of the semiconductor light emitting device 150, and the light emission of the semiconductor light emitting device 150 are performed through the first assembling wiring 321 and the second assembling wiring 322, so that the structure is simple, and manufacturing costs can be reduced, thereby improving productivity.

In addition, the adhesive part 380 remains in the commercialized display device, so that product reliability can be improved by strengthening the fixation of the semiconductor light emitting device 150.

Additional scope of applicability of the embodiments will become apparent from the detailed description that follows. However, since various changes and modifications within the spirit and scope of the embodiments can be clearly understood by those skilled in the art, the detailed description and specific embodiments, such as preferred embodiments, should be understood as being given by way of example only.

### BRIEF DESCRIPTION OF THE DRAWINGS

FIG. 1 shows a living room of a house where a display device according to an embodiment is disposed.

FIG. 2 is a block diagram schematically showing a display device according to an embodiment.

FIG. 3 is a circuit diagram showing an example of the pixel of FIG. 2.

FIG. 4 is an enlarged view of a first panel area in the display device of FIG. 1.

FIG. 5 is an enlarged view of area A2 in FIG. 4.

FIG. 6 is a diagram showing an example in which a light emitting device according to an embodiment is assembled on a substrate by a self-assembly method.

FIG. 7 is a cross-sectional view showing a display device according to an embodiment.

FIG. 8 is a cross-sectional view showing the semiconductor light emitting device of FIG. 7 in detail.

FIG. 9 is a cross-sectional view showing an adhesive part according to a first embodiment.

FIG. 10 is a cross-sectional view showing an adhesive part according to a second embodiment.

FIGS. 11 to 21 are diagrams explaining a method of manufacturing a display device according to an embodiment.

The sizes, shapes, dimensions, etc. of elements shown in the drawings can differ from actual ones. In addition, even if the same elements are shown in different sizes, shapes, dimensions, etc. between the drawings, this is only an example on the drawing, and the same elements have the same sizes, shapes, dimensions, etc. between the drawings.

### DETAILED DESCRIPTION OF EMBODIMENTS

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there can be directly on the other element or be other intermediate elements therebetween.

A display device described in this specification can comprise a TV, a signage, a mobile phone, a smart phone, a head-up display (HUDs) for automobiles, a backlight unit for a laptop computer, and a display for VR or AR. etc. However, the configuration according to the embodiment described in this specification can be applied to a device capable of displaying even if it is a new product type that is developed in the future.

Hereinafter, a light emitting device according to an embodiment and a display device comprising the same will be described.

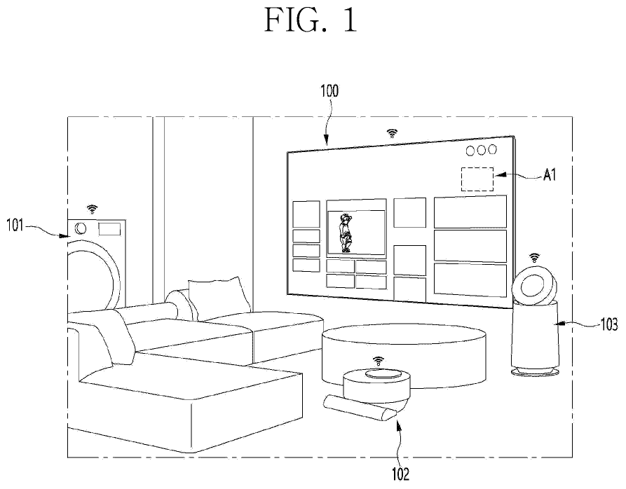

FIG. 1 illustrates a living room of a house, in which a display device is disposed, according to the embodiment.

Referring to FIG. 1, according to the embodiment, a display device 100 can display the status of various electronic devices, such as a washing machine 101, a robot cleaner 102, or an air purifier 103, can make communication with various electronic products based on Internet of Things (IOT), and can control various electronic products based on the setting data of a user.

According to the embodiment, the display device 100 can comprise a flexible display manufactured on a thin and flexible substrate. The flexible display can maintain the characteristic of an existing flat panel display, and can be bendable and rollable, like paper.

Visible information in the flexible display device can be realized by independently controlling the emitting of light from unit pixels disposed in the form of a matrix. The unit pixel is the minimum pixel to realize one color. The unit pixel of the flexible display device can be realized with a light emitting device. According to an embodiment, the light emitting device can comprise, but is not limited to, a micro-LED or a nano-LED.

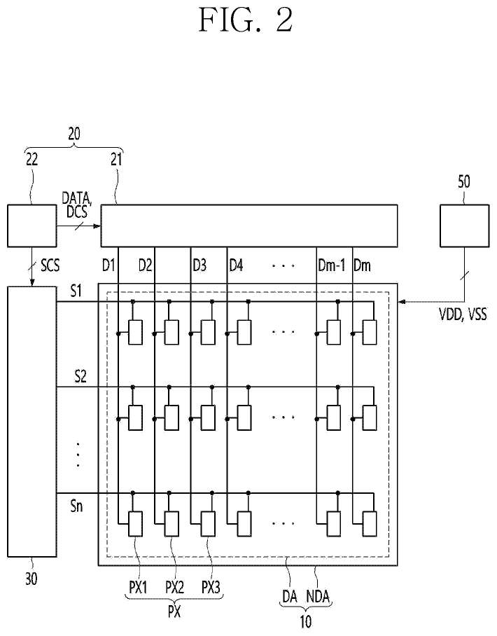

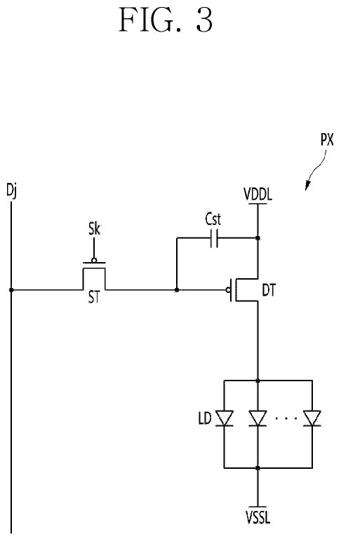

FIG. 2 is a block diagram schematically illustrating a display device according to the embodiment, and FIG. 3 is a circuit diagram illustrating a pixel of FIG. 2.

Referring to FIGS. 2 and 3, according to the embodiment, the display device 100 can comprise a display panel 10, a driving circuit 20, a scan driver 30, and a power supply circuit 50.

According to an embodiment, the display device 100 can drive the light emitting device in an active matrix (AM) manner or a passive matrix (PM) manner.

The driving circuit 20 can comprise a data driver 21 and a timing controller 22.

The display panel 10 can have, but is not limited to, the shape of a rectangle. In other words, the display panel 10 can be formed in a circular shape or an oval shape. At least one side of the display panel 10 can be formed to be bent with a specific curvature.

The display panel 10 can be divided into a display region DA and a non-display region NDA disposed at a peripheral portion of the display region DA. The display region DA has pixels PX formed therein to display an image. The display panel 10 can comprise data lines D1-Dm (m is an integer value equal to or greater than 2), scan lines S1-Sn (n is an integer value equal to or greater than 2) crossing the data lines D1-Dm, a high-potential voltage line to supply a high-potential voltage, a low-potential voltage line to supply a low-potential voltage, and pixels PX connected with the data lines D1-Dm and the scan lines S1-Sn.

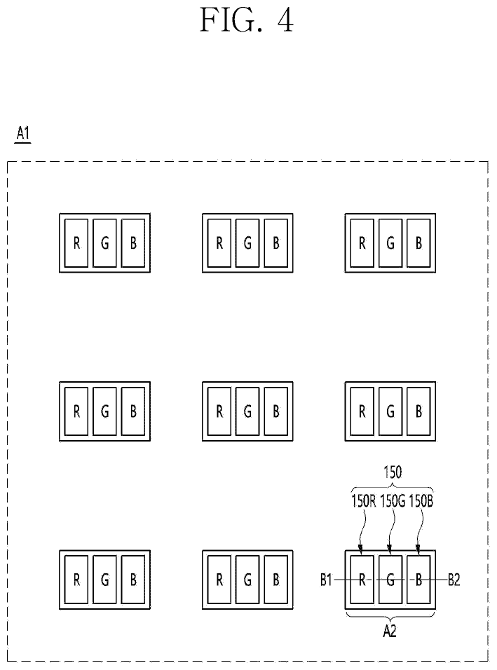

Each pixel PX can comprise a first sub-pixel PX1, a second sub-pixel PX2, and a third sub-pixel PX3. The first sub-pixel PX1 can emit first color light having a first main wavelength, the second sub-pixel PX2 can emit second color light having a second main wavelength, and the third sub-pixel PX3 can emit third color light having a third main wavelength. The first color light can be red light, the second color light can be green light, and the third color light can be blue light, but the embodiment is not limited thereto. In addition, although FIG. 4 illustrates that each pixel PX includes three sub-pixels, the embodiment is not limited thereto. In other words, each pixel PX can comprise at least four sub-pixels.

Each of the first sub-pixel PX1, the second sub-pixel PX2, and the third sub-pixel PX3 can be connected with at least one of the data lines D1-Dm, at least one of the scan lines S1-Sn, and the high-potential voltage line, respectively. The first sub-pixel PX1 can comprise light emitting devices LD, a plurality of transistors to supply currents to the light emitting devices LD, and at least one capacitor Cst, as illustrated in FIG. 3.

Although not illustrated in the drawings, each of the first sub-pixel PX1, the second sub-pixel PX2, and the third sub-pixel PX3 can comprise only one light emitting device LD and at least one capacitor Cst.

Each of light emitting devices LD can be a semiconductor light emitting diode comprising a first electrode, a plurality of conductivity type semiconductor layers, and a second electrode. In this instance, the first electrode can be an anode electrode, and the second electrode can be a cathode electrode, but the embodiment is not limited thereto.

The light emitting device can be one of a lateral-type light emitting device, a flip chip-type light emitting device, and a vertical-type light emitting device.

A plurality of transistors can comprise a driving transistor DT to supply a current to the light emitting devices LD and a scan transistor ST to supply a data voltage to a gate electrode of the driving transistor DT, as illustrated in FIG. 3. The driving transistor DT can comprise a gate electrode connected with a source electrode of the scan transistor ST, a source electrode connected with a high-potential voltage line to which a high-potential voltage is applied, and a drain electrode connected with first electrodes of the light emitting devices LD. The scan transistor ST can comprise a gate electrode connected with a scan line Sk (k is an integer value satisfying 1≤k≤n), the source electrode connected with the gate electrode of the driving transistor DT, and a drain electrode connected with a data line Dj (j is an integer value satisfying 1≤j≤m).

The storage capacitor Cst is formed between the gate electrode and the source electrode of the driving transistor DT. The storage capacitor Cst is charged with the difference between a gate voltage and a source voltage of the driving transistor DT.

The driving transistor DT and the scan transistor ST can be formed with thin film transistors. In addition, the above description has been made with reference to FIG. 3 while focusing on that the driving transistor DT and the scan transistor ST are realized with p-type metal oxide semiconductor field effect transistors (MOSFET), but the embodiment is not limited thereto. The driving transistor DT and the scan transistor ST can be realized with an N-type MOSFET. In this instance, the positions of a source electrode and a drain electrode can be changed in each of the driving transistor DT and the scan transistor ST.

In addition, in FIG. 3, each of the first sub-pixel PX1, the second sub-pixel PX2, the third sub-pixel PX3 has a 2 transistor-1 capacitor (2T1C) structure having one driving transistor DT, one scan transistor ST, and one capacitor Cst, but the embodiment is not limited thereto. Each of the first sub-pixel PX1, the second sub-pixel PX2, the third sub-pixel PX3 can comprise a plurality of scan transistors ST and a plurality of storage capacitors Cst.

Since the second sub-pixel PX2 and the third sub-pixel PX3 are expressed in the substantially same circuit diagram as that of the first sub-pixel PX1, the details thereof will be omitted below.

The driving circuit 20 outputs signals and voltages for driving the display panel 10. The driving circuit 20 can comprise the data driver 21 and the timing controller 22.

The data driver 21 receives digital video data DATA and a source control signal DCS from the timing controller 22. The data driver 21 converts the digital video data DATA into analog data voltages in response to the source control signal DCS and supplies the analog data voltages to the data lines D1-Dm of the display panel 10.

The timing controller 21 receives the digital video data DATA and timing signals from a host system. The timing signals can comprise a vertical sync signal, a horizontal sync signal, a data enable signal, and a dot clock. The host system can be an application processor of a smartphone or a tablet PC, a monitor, or a system on chip of a television (TV).

The timing controller 22 generates control signals for controlling the operating timing of the data driver 21 and the scan driver 30. The control signals can comprise a source control signal DCS for controlling the operating timing of the data driver 21 and a scan control signal SCS for controlling the operating timing of the scan driver 30.

The driving circuit 20 can be disposed in the non-display region NDA provided at one side of the display panel 10. The driving circuit 20 can be provided in the form of an integrated circuit (IC), and can be mounted in a chip on glass (COG) manner, a chip on plastic (COP) manner, or an ultrasonic wave bonding manner on the display panel 10, but the embodiment is not limited thereto. For example, the driving circuit 20 can be mounted on a circuit board (not illustrated) instead of the display panel 10.

The data driver 21 can be mounted on in a chip on glass (COG) manner, a chip on plastic (COP) manner, or an ultrasonic wave bonding manner on the display panel 10, and the timing controller 21 can be mounted on the circuit board.

The scan driver 30 receives a scan control signal SCS from the timing controller 22. The scan driver 30 generate scan signals in response to the scan control signal SCS and supplies the scan signals to the scan lines S1-Sn of the display panel 10. The scan driver 30, which comprises a plurality of transistors, can be formed in the non-display region NDA of the display panel 10. Alternatively, the scan driver 30 can be provided in the form of the IC. In this instance, the scan driver 30 can be mounted on a flexible gate film attached to another side of the display panel 10.

The circuit board can be attached onto pads provided at one edge of the display panel 10 using an anisotropic conductive film. Due to this, lead lines of the circuit board can be electrically connected with pads. The circuit board can be a flexible film such as a flexible printed circuit board, a printed circuit board, or a chip on film. The circuit board can be bent below the display panel 10. Due to this, one side of the circuit board can be attached to one edge of the display panel 10, and an opposite side of the circuit board can be disposed below the display panel 10 and connected with a system board on which the host system is mounted.

A power supply circuit 50 can generate voltages necessary for driving the display panel 10, based on main power applied from the system board and can apply the voltages to the display panel 10. For example, the power supply circuit 50 can generate a high-potential voltage VDD and a low-potential voltage VSS for driving the light emitting devices LD of the display panel 10, based on the main power, and can supply the high-potential voltage VDD and the low-potential voltage VSS to the high-potential voltage line and the low-potential voltage line of the display panel 10. In addition, the power supply circuit 50 can generate driving voltages for driving the driving circuit 20 and the scan driver 30, based on the main power, and can supply the driving voltages to the driving circuit 20 and the scan driver 30.

FIG. 4 is an expanded view of a first panel region in the display device of FIG. 3.

Referring to FIG. 4, according to the embodiment, the display device 100 manufactured, as a plurality of panel regions, such as a first panel region A1, are mechanically or electrically connected with each other through tiling.

The first panel region A1 can comprise a plurality of light emitting devices 150 disposed according to unit pixels (reference numeral PX of FIG. 2).

For example, each pixel PX can comprise a first sub-pixel PX1, a second sub-pixel PX2, and a third sub-pixel PX3. For example, a plurality of red light emitting device 150R can be disposed in the first sub-pixel PX1, a plurality of green light emitting devices 150G can be disposed in the second sub-pixel PX2, and a plurality of blue light emitting devices 150B can be disposed in the third sub-pixel PX3. The unit pixel PX can further include a fourth sub-pixel having no the light emitting device, but the embodiment is not limited thereto.

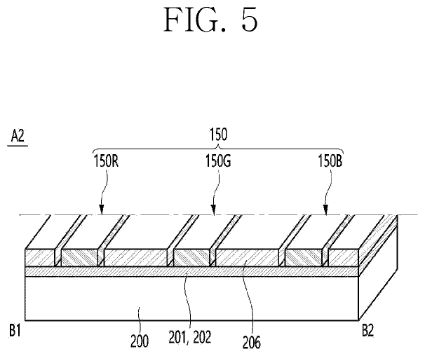

FIG. 5 is an enlarged view of region A2 of FIG. 4.

Referring to FIG. 5, according to the embodiment, the display device 100 can comprise a substrate 200, assembling wirings 201 and 202, an insulating layer 206, and a plurality of light emitting devices 150. The display device 100 can further include a larger number of components.

The assembling wirings can comprise a first assembling wiring 201 and a second assembling wiring 202 spaced apart from each other. The first assembling wiring 201 and the second assembling wiring 202 can be provided to generate the dielectrophoretic force for assembling the light emitting device 150. The light emitting device 150 can be one of a lateral-type light emitting device, a flip chip-type light emitting device, and a vertical-type light emitting device.

The light emitting device 150 can comprise a red light emitting device 150R, a green light emitting device 150G, and a blue light emitting device 150B, but the embodiment is not limited thereto. For example, the light emitting device 150 can comprise a red phosphor and a green phosphor to realize a red color and a green color, respectively.

The substrate 200 can be a support member that supports components disposed on the substrate 200 or a protection member that protects the components.

The substrate 200 can comprise a rigid substrate or a flexible substrate. The substrate 200 can comprise glass or polyimide. Alternatively, the substrate 200 can comprise a flexible material, such as polyethylene naphthalate (PEN), or polyethylene terephthalate (PET). Alternatively, the substrate 200 can comprise a transparent material, but the embodiment is not limited thereto.

The substrate 200 is a backplane equipped with circuits in the sub-pixels PX1, PX2 and PX3 shown in FIGS. 2 and 3, such as transistors ST and DT, capacitors Cst, signal wiring, etc., but is not limited thereto.

The insulating layer 206 can comprise an insulating and flexible organic material such as polyimide, PAC, PEN, PET, polymer, etc. or an inorganic material such as silicon oxide (SiO2) or silicon nitride (SiNx), and can be integrated with the substrate 200 to form one substrate.

The insulating layer 206 can be a conductive adhesive layer having an adhesive property and a conductive property. The conductive adhesive layer can have a flexible property such that the display device 100 has a flexible function. For example, the insulating layer 206 can be an anisotropy conductive film (ACF) or a conductive adhesive layer comprising an anisotropy conductive medium or conductive particle. The conductive adhesive layer can be a layer having electrical conductivity in a vertical direction with respect to the thickness thereof, but having an electrically insulating property in a horizontal direction with respect to the thickness thereof.

The insulating layer 206 can comprise an assembling hole 203 to insert the light emitting device 150. Accordingly, the light emitting device 150 can be easily inserted into the assembling hole 203 of the insulating layer 206, in self-assembling. The assembling hole 203 can be named as an insertion hole, a fixing hole, and an alignment hole.

The assembly hole 203 can be different depending on the shape of the semiconductor light emitting device 150. For example, the red semiconductor light emitting device, the green semiconductor light emitting device, and the blue semiconductor light emitting device each can have different shapes, and can have an assembly hole 203 having a shape corresponding to the shape of each of these semiconductor light emitting devices. For example, the assembly hole 203 can comprise a first assembly hole for assembling a red semiconductor light emitting device, a second assembly hole for assembling a green semiconductor light emitting device, and a third assembly hole for assembling a blue semiconductor light emitting device. For example, the red semiconductor light emitting device can have a circular shape, the green semiconductor light emitting device can have a first oval shape with a first minor axis and a second major axis, and the blue semiconductor light emitting device can have a second oval shape with a second minor axis and a second major axis, is not limited thereto. The second major axis of the oval shape of the blue semiconductor light emitting device can be greater than the second major axis of the oval shape of the green semiconductor light emitting device, and the second minor axis of the oval shape of the blue semiconductor light emitting device can be smaller than the first minor axis of the oval shape of the green semiconductor light emitting device.

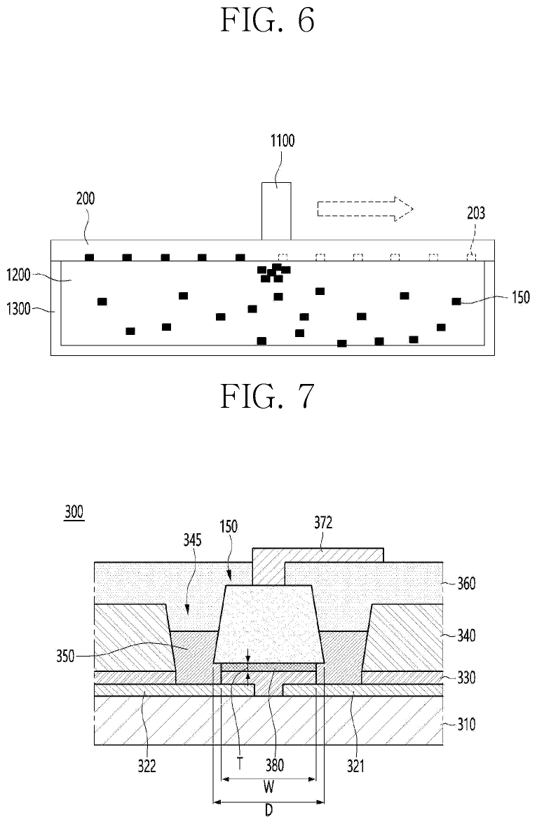

FIG. 6 shows that a light emitting device is assembled with a substrate through a self-assembly method according to the embodiment.

The self-assembly method of the light emitting device will be described with reference to FIGS. 5 and 6.

The substrate 200 can be a panel substrate of the display device. Although the following description is described while focusing on the substrate 200 is the panel substrate, the embodiment is not limited thereto.

The substrate 200 can comprise glass or polyimide. In addition, the substrate 200 can comprise a material, such as PEN or PET, having flexibility. Alternatively, the substrate 200 can comprise a transparent material, but the embodiment is not limited thereto.

Referring to FIG. 6, the light emitting device 150 can be introduced into a chamber 1300 filled with a fluid 1200. The fluid 1200 can be de-ionized water, but the embodiment is not limited thereto. The chamber 1300 can be classified into a bath, a container, or a vessel.

Thereafter, the substrate 200 can be disposed on the chamber 1300. According to an embodiment, the substrate 200 can be introduced into the chamber 1300.

As illustrated in FIG. 5, a pair of assembling wirings 201 and 202, which correspond to the light emitting device 150 to be assembled, can be disposed in the substrate 200.

The assembling wirings 201 and 202 can comprise a transparent electrode (ITO), or a metal material having excellent conductivity. For example, the assembling wirings 201 and 202 can comprise at least one of titanium (Ti), chromium (Cr), nickel (Ni), aluminum (Al), platinum (Pt), gold (Au), tungsten (W), or molybdenum (Mo), or the alloy thereof.

The assembling wirings 201 and 202 can form an electric field by the voltage supplied from the outside, and the dielectrophoretic force can be formed between the assembling wirings 201 and 202 due to the electric field. The light emitting device 150 can be fixed into the assembling hole 203 on the substrate 200 by the dielectrophoretic force.

The interval between the assembling wirings 201 and 202 is formed to be smaller than the width of the light emitting device 150 and the width of the assembling hole 203, such that the assembling position of the light emitting device 150 using the electric field can be more precisely fixed.

The insulating layer 206 can be formed on the assembling wirings 201 and 202 to protect the assembling wirings 201 and 202 from the fluid 1200, and to prevent a current, which flows through the assembling wirings 201 and 202, from leaking. The insulating layer 206 can be formed in a single layer or a multi-layer comprising an inorganic insulator, such as silica or alumina, or an organic insulator.

The insulating layer 206 can comprise a material, such as polyimide, PEN or PET, having an insulating property and a flexible property, and can be integrated with the substrate 200 to form one substrate.

The insulating layer 206 can comprise an insulating layer with adhesiveness or a conductive insulating layer with conductivity. The insulating layer 206 can have a flexible property such that the display device 100 has a flexible function.

The insulating layer 206 can have a barrier rib, and the assembling hole 203 can be formed by the barrier rib. For example, when the substrate 200 is formed, a part of the insulating layer 206 is removed, such that each light emitting device 150 is assembled with the assembling hole 203 of the insulating layer 206.

The substrate 200 can have assembling holes 203 coupled to light emitting devices 150, and the surface, which has the assembling hole 203, of the substrate 200 can make contact with the fluid 1200. The assembling hole 203 can guide the accurate assembling position of the light emitting device 150.

Meanwhile, the assembling hole 203 can have the shape and the size corresponding to the shape of the light emitting device 150 to be assembled at the corresponding position. Accordingly, another light emitting device or a plurality of light emitting devices can be prevented from being assembled into the assembling hole 203.

Referring back to FIG. 6, after the substrate 200 is disposed, an assembly device 1100 comprising a magnetic substance can move along the substrate 200. The magnetic substance can comprise a magnet or an electromagnet. The assembly device 1100 can move while making contact with the substrate 200, such that a region influenced by a magnetic field is present in the fluid 1200 as much as possible. According to an embodiment, the assembly device 1100 can comprise a plurality of magnetic substances or can comprise a magnetic substance corresponding to the substrate 200. In this instance, the moving distance of the assembly device 1100 can be limited to be in a specific range.

The light emitting device 150 in the chamber 1300 can move toward the assembly device 1100 due to the magnetic field generated by the assembly device 1100.

The light emitting device 150 can be introduced into the assembling hole 203 to make contact with the substrate 200, while moving toward the assembly device 1100.

In this instance, the electric field applied by the assembling wirings 201 and 202 formed on the substrate 200 can prevent the light emitting device 150, which makes contact with the substrate 200, from being detached from the substrate 200 by the movement of the assembly device 1100.

In other words, the self-assembly method using an electromagnetic field can sharply reduce a time taken when each light emitting device 150 is assembled with the substrate 200. Accordingly, a large-area and high-pixel-density display can be more rapidly and economically realized.

A solder layer (not illustrated) can be additionally formed between the light emitting device 150, which is assembled with the assembling hole 203 in the substrate 200, and the substrate 200, such that the bonding force of the light emitting device 150 can be improved.

Thereafter, an electrode wiring (not illustrated) is connected with the light emitting device 150 to apply power to the light emitting device 150.

Hereinafter, although not illustrated, at least one insulating layer can be formed through the following process. The at least one insulating layer can comprise a transparent resin or a resin comprising a reflective material or a scattering material.

Meanwhile, according to the embodiment, since an adhesive part is formed in the assembly hole for each sub-pixel through particle-level control, the semiconductor light emitting device assembled in the assembly hole can be fixed to the substrate through the adhesive part, so that the semiconductor light emitting device does not fall off even if post-processing is performed. Accordingly, yield and lighting can be improved. In particular, through particle-level control, the adhesive part can be easily formed even within the assembly hole of a sub-pixel at high resolution or ultra-high resolution, and thus yield and lighting can be improved even at high resolution or ultra-high resolution.

Descriptions omitted below can be easily understood from the description given above in relation to FIGS. 1 to 6 and the corresponding drawings.

FIG. 7 is a cross-sectional view showing a display device according to an embodiment.

Referring to FIG. 7, a display device 300 according to an embodiment can comprise a substrate 310, a barrier rib 340, a semiconductor light emitting device 150, and an adhesive part 380. The display device 300 according to an embodiment can comprise a first assembling wiring 321, a second assembling wiring 322, and a first insulating layer 330. The display device 300 according to the embodiment can comprise a connection electrode 350, a second insulating layer 360, and an electrode wiring 372. The display device 300 according to an embodiment can comprise more components than these.

Since each of the substrate 310 and the barrier rib 340 is the same as the substrate 200 and the insulating layer 206 shown in FIG. 5, detailed descriptions are omitted.

The barrier rib 340 can be disposed on the substrate 310. For example, the barrier rib 340 can be disposed on the first assembling wiring 321 and the second assembling wiring 322. The barrier rib 340 can be referred to as an insulating layer. The barrier rib 340 can have a plurality of assembly holes 345. The assembly hole 345 can be provided in a sub-pixel of a pixel, but is not limited thereto. The assembly hole 345 can guide and fix the assembly of the semiconductor light emitting device 150, and during self-assembly, the semiconductor light emitting device 150, which is moved by a magnetic body, can be moved from near the assembly hole 345 into the assembly hole 345 and fixed in the assembly hole 345.

Although the assembly hole 345 is shown in the drawing as having an inclined inner side surface, it can also have an inner side surface that is perpendicular to the upper surface of the substrate 310. The semiconductor light emitting device 150 can be easily inserted into the assembly hole 345 by the assembly hole 345 having an inclined inner side surface.

The first assembling wiring 321 and the second assembling wiring 322 can be disposed on the substrate 310. The first assembling wiring 321 and the second assembling wiring 322 can be provided to generate dielectrophoretic force to assemble the light emitting device 150.

Although the drawing shows the first assembling wiring 321 and the second assembling wiring 322 being spaced apart from each other on the same plane, the first assembling wiring 321 and the second assembling wiring 322 can be disposed in different layers. For example, an insulating layer (not shown) can be disposed between the first assembling wiring 321 and the second assembling wiring 322, and one of the first assembling wiring 321 and the second assembling wiring 322 can be disposed below the insulating layer, and the other assembling wiring can be disposed above the insulating layer.

Since each of the first and second assembling wirings 321 and 322 is the same as the electrode wirings 201 and 202 shown in FIG. 5, detailed descriptions are omitted.

The first insulating layer 330 can be disposed on the substrate 310. The first and second assembling wirings 321 and 322 can be disposed between the first insulating layer 330 and the substrate 310. The first assembling wiring 321 and the second assembling wiring 322 can be disposed on the same layer, for example, the substrate 310. That is, the normally positioned at the center of the assembly hole 345 first assembling wiring 321 and the second assembling wiring 322 can be in contact with the upper surface of the substrate 310. The first assembling wiring 321 and the second assembling wiring 322 can be spaced apart from each other to prevent electrical short circuits. An alternating voltage can be applied to the first assembling wiring 321 and the second assembling wiring 322, so that a dielectrophoretic force can be formed between the first assembling wiring 321 and the second assembling wiring 322. The semiconductor light emitting device 150 positioned in the assembly hole 345 can be fixed by this dielectrophoretic force. Since the first assembling wiring 321 and the second assembling wiring 322 are disposed horizontally side by side on the same layer, the dielectrophoretic force formed between the first assembling wiring 321 and the second assembling wiring 322 can be uniform, so that the semiconductor light emitting device 150 can be positioned at the center of the assembly hole 345.

The first insulating layer 330 can protect the first assembling wiring 321 and the second assembling wiring 322 from fluid (1200 in FIG. 6), and can prevent leakage current flowing through the first assembling wiring 321 and the second assembling wiring 322.

The first insulating layer 330 can increase dielectrophoretic force. For example, the first insulating layer 330 can be a dielectric layer. The first insulating layer 330 can be formed of a material with a high dielectric constant. The dielectrophoretic force can be proportional to the dielectric constant of the first insulating layer 330. Accordingly, the dielectrophoretic force formed between the first assembling wiring 321 and the second assembling wiring 322 can be increased by the first insulating layer 330 made of a material with a high dielectric constant, and due to the increased dielectrophoretic force, the semiconductor light emitting device 150 positioned in the assembly hole 345 can be fixed more firmly.

For example, the first insulating layer 330 can be formed as a single layer or multilayer of an inorganic material such as silica or alumina or an organic material.

For example, the first insulating layer 330 can comprise an insulating and flexible material such as polyimide, PEN, PET, etc. For example, the first insulating layer 330 can be integrated with the substrate 310 to form one substrate. That is, the first assembling wiring 321 and the second assembling wiring 322 can be embedded in the substrate 310.

The first insulating layer 330 can be an insulating layer with adhesiveness or a conductive adhesive layer with conductivity. When the first insulating layer 330 is a conductive adhesive layer, the first assembling wiring 321 and the second assembling wiring 322 can be surrounded by an insulating layer to prevent electrical short circuit between each of the first assembling wiring 321 and the second assembling wiring 322 and the conductive adhesive layer.

The semiconductor light emitting device 150 can be disposed in each of the plurality of assembly holes 345 provided on the substrate 310.

The semiconductor light emitting device 150 can be formed of a semiconductor material, for example, a group IV compound or a group III-V compound. The semiconductor light emitting device 150 is a member that generates light according to electrical signals.

As an example, the semiconductor light emitting device 150 disposed in each assembly hole 345 can generate single color light. For example, the semiconductor light emitting device 150 can generate ultraviolet light, purple light, blue light, etc. In this instance, the semiconductor light emitting device 150 disposed in each assembly hole 345 can serve as a light source, and images can be displayed by generating light of various colors using this light source. A color conversion layer and a color filter can be provided to generate light of various colors.

As another example, the semiconductor light emitting device 150 disposed in each assembly hole 345 can be one of a blue semiconductor light emitting device, a green semiconductor light emitting device, and a red semiconductor light emitting device. For example, when three assembly holes 345 are disposed in parallel, the semiconductor light emitting device 150 disposed in the first assembly hole 345 can be a blue semiconductor light emitting device, the semiconductor light emitting device 150 disposed in the second assembly hole 345 can be a green semiconductor light emitting device, and the semiconductor light emitting device 150 disposed in the third assembly hole 345 can be a red semiconductor light emitting device.

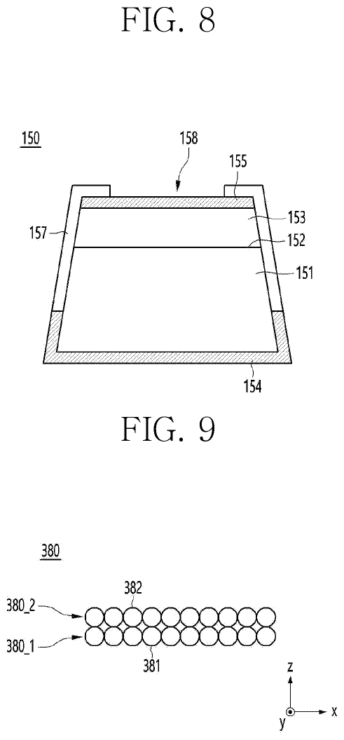

The semiconductor light emitting device 150 according to the embodiment will be described in more detail with reference to FIG. 8.

FIG. 8 is a cross-sectional view showing the semiconductor light emitting device of FIG. 7 in detail.

Referring to FIG. 8, the semiconductor light emitting device 150 according to the embodiment can comprise alight emitting part 151, 152, and 153, a first electrode 154, a second electrode 155, and a passivation layer 157. It can be included. The semiconductor light emitting device 150 according to the embodiment can comprise more components than this. The passivation layer 157 can be called an insulating layer, a protective layer, etc.

The light emitting part can comprise a first conductivity type semiconductor layer 151, an active layer 152, and a second conductivity type semiconductor layer 153. That is, the active layer 152 can be disposed on the first conductivity type semiconductor layer 151 and the second conductivity type semiconductor layer 153 can be disposed on the active layer 152, but is not limited thereto.

The first conductivity type semiconductor layer 151, the active layer 152, and the second conductivity type semiconductor layer 153 can be sequentially grown on a wafer (not shown) using deposition equipment such as MOCVD. Thereafter, the second conductivity type semiconductor layer 153, the active layer 152, and the first conductivity type semiconductor layer 151 can be etched along the vertical direction in that order using an etching process. Thereafter, the semiconductor light emitting device 150 can be manufactured by forming the passivation layer 157 along a circumference of the remaining region excluding a part of the side surface of the first conductivity type semiconductor layer 151, that is, the other part of the side surface of the first conductivity type semiconductor layer 151, the side surface of the active layer 152, and the side surface of the second conductivity type semiconductor layer 153.

The first conductivity type semiconductor layer 151 can comprise a first conductivity type dopant, and the second conductivity type semiconductor layer 153 can comprise a second conductivity type dopant. For example, the first conductivity type dopant can be an n-type dopant such as silicon (S1), and the second conductivity type dopant can be a p-type dopant such as boron (B).

For example, the first conductivity type semiconductor layer 151 can be a place to generate electrons, and the second conductivity type semiconductor layer 153 can be a place to form holes. The active layer 152 is a place that generates light and can be called a light emitting layer.

The first electrode 154 can be disposed on the lower portion of the light emitting part 151, 152, and 153. The first electrode 154 can be disposed on the side portion of the light emitting part 151, 152, and 153. The second electrode 155 can be disposed on the upper portion of the light emitting part 151, 152, and 153. The first electrode 154 and the second electrode 155 can supply current to the light emitting part 151, 152, and 153, so that the light emitting part 151, 152, and 153 can emit light with a luminance corresponding to the current.

The first electrode 154 and the second electrode 155 can be made of metal with excellent electrical conductivity. The first electrode 154 and the second electrode 155 can be made of at least one or more layers. The first electrode 154 and the second electrode 155 can be made of different metals, but are not limited thereto.

For example, at least one of the first electrode 154 and the second electrode 155 can comprise a magnetic layer. For example, as shown in FIG. 6, when magnetized by the magnetic body of the assembly device 1100, the semiconductor light emitting device 150 comprising a magnetic layer can be moved toward the magnetic body by applying an attractive force to the magnetic body of the assembly device 1100. Accordingly, the semiconductor light emitting device 150 can be moved along the movement direction of the magnetic body of the assembly device 1100. In this way, the moving semiconductor light emitting device 150 can be pulled by the dielectrophoretic force formed in the assembly hole 345 on the substrate 310 and assembled in the assembly hole 345.

Meanwhile, the first electrode 154 can comprise a reflective layer. In this instance, light generated in the active layer 152 can be reflected, thereby improving light extraction efficiency and improving luminance.

The passivation layer 157 can be disposed on the side portion of the light emitting part 151, 152, and 153. The passivation layer 157 can be disposed on the upper portion of the light emitting part 151, 152, and 153. For example, the passivation layer 157 can be disposed on the second electrode 155 of the light emitting part 151, 152, and 153.

For example, the passivation layer 157 can protect the light emitting part 151, 152, and 153.

For example, the passivation layer 157 can block leakage current of the light emitting part 151, 152, and 153. Leakage current can flow through the side portion of the light emitting part 151, 152, and 153, that is, the side surface of the first conductivity type semiconductor layer 151, the side surface of the active layer 152, and the side surface of the second conductivity type semiconductor layer 153. By forming the passivation layer 157 on the side surface of the first conductivity type semiconductor layer 151, the side surface of the active layer 152, and the side surface of the second conductivity type semiconductor layer 153, leakage current can be prevented.

For example, the passivation layer 157 can help assemble the semiconductor light emitting device 150. That is, by adjusting the placement area of the first electrode 154 and the passivation layer 157 disposed on the outer side surface of the semiconductor light emitting device 150, the semiconductor light emitting device 150 can be pulled into the assembly hole 345 by the dielectrophoretic force formed between the first assembling wiring 321 and the second assembling wiring 322. For example, the first electrode 154 of the semiconductor light emitting device 150 can be disposed close to the first assembling wiring 321 and the second assembling wiring 322, and the passivation layer 157 can be disposed away from the first assembling wiring 321 and the second assembling wiring 322, so that the semiconductor light emitting device 150 can be pulled into the assembly hole 345 by dielectrophoretic force. Accordingly, the semiconductor light emitting device 150 can be pulled into the assembly hole 345 by the dielectrophoretic force and then continuously fixed within the assembly hole 345. Afterwards, even if dielectrophoretic force is not generated, the semiconductor light emitting device 150 can be fixed in the assembly hole 345 by natural forces such as surface tension or van der Waals force.

For example, an opening 158 in which the passivation layer 157 is not formed can be formed in a part of the second electrode 155 of the light emitting part 151, 152, and 153. As will be explained later, the electrode wiring 372 can be electrically connected to the second electrode 155 of the semiconductor light emitting device 150 through the opening 158.

Meanwhile, the passivation layer 157 can be formed on a part of the side portion of the light emitting part 151, 152, and 153. That is, the passivation layer 157 can be disposed on a part on the side portion of the light emitting part 151, 152, and 153, and the first electrode 154 can be disposed on the other part of the side portion of the light emitting part 151, 152, and 153.

The first electrode 154 can be formed on the side portion of the light emitting part 151, 152, and 153 in order to easily connect the first electrode 154 electrically to the connection electrode 350. As the first electrode 154 is formed to have a larger area on the side portion of the light emitting part 151, 152, and 153, the contact area between the connection electrode 350 and the first electrode 154 can be larger. In this instance, current can flow more smoothly through the light emitting part 151, 152, and 153 to output more light, which means that luminance is improved.

Referring again to FIG. 7, the adhesive part 380 can be disposed between the substrate 310 and the semiconductor light emitting device 150, thereby enhancing the fixation of the semiconductor light emitting device 150. For example, the adhesive part 380 can be disposed within the assembly hole 345. For example, the adhesive part 380 can be disposed between the substrate 310 and the semiconductor light emitting device 150 within the assembly hole 345. For example, the adhesive part 380 can be disposed between the first insulating layer 330 and the semiconductor light emitting device 150 within the assembly hole 345 to attach the semiconductor light emitting device 150 to the first insulating layer 330. The fixation of the semiconductor light emitting device 150 can be strengthened.

In the process procedure, after the semiconductor light emitting device 150 is assembled, a process of partially removing the first insulating layer 330 to expose the first assembling wiring 321 and/or the second assembling wiring 322, a process of forming the connection electrode 350, a process of forming the second insulating layer 360, a process of forming a contact hole in the second insulating layer 360, a process of forming the electrode wiring 372 to be electrically connected to the semiconductor light emitting device 150 through a contact hole, etc. can be performed.

The semiconductor light emitting device 150 can temporarily stay in the assembly hole 345 by the dielectrophoretic force formed between the first assembling wiring 321 and the second assembling wiring 322, and during each of these processes, the semiconductor light emitting device 150 can fall out of the assembly hole 345.

As described above, a method of fixing the semiconductor light emitting device 150 by a photoresist film formed around the semiconductor light emitting device 150 within the assembly hole 345 has been proposed. While the substrate is rotated to form a photoresist film, a coating liquid is coated to form a photoresist film. When the substrate is rotated, the semiconductor light emitting device 150 moves out of the assembly hole 345. In addition, since the photoresist film must be removed to form the connection electrode 350, an additional process is required, which increases manufacturing cost and process time.

As another method, there is a method of forming an adhesive pattern on each of a plurality of sub-pixels on the substrate. However, there is a problem that it is physically and process-wise difficult to form an ultra-small adhesive pattern on each of a plurality of sub-pixels at high resolution or ultra-high resolution. In particular, when misalignment occurs when the process error is very small, a defect can occur in which an adhesive pattern is formed between a plurality of sub-pixels rather than inside each sub-pixel.

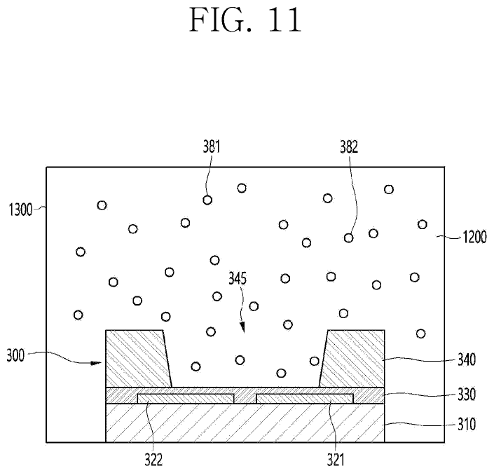

In the first embodiment, the adhesive part 380 can be formed in sub-pixel units through particle-level control. In this way, since the semiconductor light emitting device 150 is stably fixed to the first insulating layer 330 through the adhesive part 380 formed in sub-pixel units, even if a post-process is performed, the semiconductor light emitting device 150 does not fall out of the assembly hole 345, thereby improving yield, and through this improved yield, defective light emission can be minimized and the lighting yield can be improved. The particle-level control is explained in detail in the manufacturing process of the display device 300 (FIGS. 11 to 21).

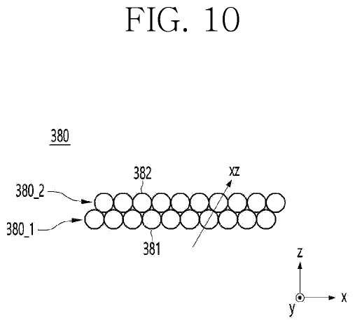

The adhesive part 380 will be described with reference to FIGS. 9 and 10.

The adhesive part 380 can comprise adhesive particles 381 and 382 in contact with each other. The adhesive particles 381 and 382 in contact with each other can be stacked. For example, the adhesive particles 381 and 382 in contact with each other can be stacked along a horizontal direction (x). For example, the adhesive particles 381 and 382 in contact with each other can be stacked along a vertical direction (y). For example, the adhesive particles 381 and 382 in contact with each other can be stacked along a diagonal direction (xz).

Although the adhesive particles 381 and 382 are shown in the drawing as having the same diameter, they can have different diameters or random diameters. Even though the adhesive particles 381 and 382 have different or random diameters, the adhesive particles 381 and 382 can be stacked in contact with each other in the assembly hole 345 by the dielectrophoretic force formed between the assembling wirings 321 and 322.

The adhesive part 380 can comprise multiple layers. For example, the adhesive part 380 can comprise a first adhesive layer 380_1 and a second adhesive layer 3802, but is not limited thereto. Although the drawing shows two layers 3801 and 3802 along the vertical direction (z), three or more layers can be included.

For example, the first adhesive layer 380_1 can comprise a plurality of first adhesive particles 381, and the second adhesive layer 380_2 can comprise a plurality of second adhesive particles 382.

The first adhesive particles 381 and the second adhesive particles 382 can have adhesive properties. That is, since the surface of each of the first adhesive particles 381 and the second adhesive particles 382 is a surface with adhesive force, the first adhesive particles 381, the second adhesive particles 382, and the first adhesive particles 381 and the second adhesive particles 382 can be adhered to each other.

In the drawing, a plurality of first adhesive particles 381 of the first adhesive layer are shown to be located on a first straight line, and a plurality of second adhesive particles 382 of the second adhesive layer are shown to be located on a second straight line, but the plurality of first adhesive particles 381 of the first adhesive layer can deviate from a first straight line within a certain range, and the plurality of second adhesive particles 382 of the second adhesive layer can deviate from a second straight line within a certain range. For example, the certain range can be the radius of the first adhesive particle 381 or the second adhesive particle 382, but is not limited thereto.

As shown in FIG. 9, the plurality of first adhesive particles 381 of the first adhesive layer can be in contact with each other along the horizontal direction, and the plurality of second adhesive particles 382 of the second adhesive layer can be in contact with each other along the horizontal direction. For example, the plurality of first adhesive particles 381 of the first adhesive layer can each overlap other along the horizontal direction, and the plurality of second adhesive particles 382 of the second adhesive layer can each overlap other along the horizontal direction.

The plurality of first adhesive particles 381 of the first adhesive layer can contact each other along the vertical direction (z), and the plurality of second adhesive particles 382 of the second adhesive layer can contact each other along the vertical direction. For example, the plurality of first adhesive particles 381 of the first adhesive layer can each overlap other along the vertical direction, and the plurality of second adhesive particles 382 of the second adhesive layer can each overlap other along the vertical direction.

As shown in FIG. 10, the plurality of first adhesive particles 381 of the first adhesive layer can each overlap other along the diagonal direction (xz), and the plurality of second adhesive particles 382 of the second adhesive layer can each overlap other along the diagonal direction. For example, the plurality of first adhesive particles 381 of the first adhesive layer can be in contact with each other along the diagonal direction, and the plurality of second adhesive particles 382 of the second adhesive layer can be in contact with each other along the diagonal direction.

As described above, since the first adhesive particles 381, the second adhesive particles 382, and the first adhesive particles 381 and the second adhesive particles 382 included in the adhesive part 380 can be adhered to each other, the semiconductor light emitting device 150 can be firmly attached to the first insulating layer 330 by the adhesive part 380, so that the semiconductor light emitting device 150 does not fall out of the assembly hole 345 even when a post-process is performed. Therefore, a decrease in yield and lighting yield due to separation of the semiconductor light emitting device 150 can be prevented.

Meanwhile, the adhesive part 380 is sufficient as long as it is large enough to firmly fix the semiconductor light emitting device 150 to the first insulating layer 330. Therefore, even if the width W of the adhesive part 380 is smaller than the diameter D of the semiconductor light emitting device 150, the adhesive part 380 can firmly fix the semiconductor light emitting device 150 to the first insulating layer 330. In this instance, the connection electrode 350 can in contact with the side portion of the adhesive part 380 between the semiconductor light emitting device 150 and the first insulating layer 330. Therefore, since the connection electrode 350 is electrically connected not only to the side portion of the semiconductor light emitting device 150 but also to the lower portion of the semiconductor light emitting device 150, a smoother voltage supply is possible by expanding the contact area, thereby improving luminance. In addition, since the connection electrode 350 is in contact with not only the semiconductor light emitting device 150, the first assembling wiring 321 and/or the second assembling wiring 322, and the barrier rib 340, but also the side portion of the adhesive part 380, product reliability can be improved by strengthening the fixation of the connection electrode 350.

The adhesive part 380 can have a relatively thin thickness T. For example, the thickness T of the adhesive part 380 can be 10 nm to 1 μm. For example, the thickness T of the adhesive part 380 can be 10 nm to 500 nm. For example, the thickness T of the adhesive part 380 can be 10 nm to 200 nm. For example, the thickness T of the adhesive part 380 can be 30 nm to 100 nm. Accordingly, since the thickness T of the adhesive part 380 is thin, the thickness of the display device 300 can also be thin.

The adhesive part 380 (or the adhesive particles 381 and 382) can be at least one of an organic material, a photo-curable material, and a dielectric material. For example, the adhesive part 380 can be polyvinyl alcohol (PVA), but is not limited thereto. The adhesive particles 381 and 382 can be in powder form. If the adhesive part is made of a photo-curable material, it can be a material that is cured by, for example, ultraviolet light. When the adhesive part 380 is made of a dielectric material, it is more greatly influenced by the dielectrophoretic force formed between the first assembling wiring 321 and the second assembling wiring 322, so that particle-level control of the adhesive particles 381 and 382 included in the adhesive part 380 can be easily performed.

Meanwhile, the connection electrode 350 can be disposed in the assembly hole 345. The connection electrode 350 can be called a connection part, a connection member, a connection metal, etc.

The connection electrode 350 can connect the semiconductor light emitting device 150 to at least one of the first and second assembling wirings 321 and 322. The connection electrode 350 can be made of a metal with excellent electrical conductivity. The connection electrode 350 can be made of at least one or more layers. For example, the connection electrode 350 can be made of three layers of molybdenum/aluminum/molybdenum (Mo/Al/Mo), but is not limited thereto.

For example, the connection electrode 350 can be disposed along a circumference of the side portion of the semiconductor light emitting device 150 within the assembly hole 345. For example, the connection electrode 350 can be electrically connected to the side portion of the semiconductor light emitting device 150 along the circumference of the side portion of the semiconductor light emitting device 150 within the assembly hole 345.

As described above, the connection electrode 350 can be in contact with the side portion of the adhesive part 380, thereby strengthening the fixation of the connection electrode 350.

The second insulating layer 360 can be formed of an organic material or an inorganic material. For example, the second insulating layer 360 can be disposed on the semiconductor light emitting device 150 and the barrier rib 340. The second insulating layer 360 can be disposed in the assembly hole 345. For example, the second insulating layer 360 can be disposed in the groove formed by the connection electrode 350 within the assembly hole 345.

For example, a part of the second insulating layer 360 can be removed to form a contact hole exposing the second electrode 155 of the semiconductor light emitting device 150. The electrode wiring 372 can be electrically connected to the second electrode 155 of the semiconductor light emitting device 150 through this contact hole.

The electrode wiring 372 can be connected to the second electrode 155 of the semiconductor light emitting device 150. At least one of the first assembling wiring 321 and the second assembling wiring 322 can be named a first electrode 154 wiring, and the electrode wiring 372 can be named a second electrode 155 wiring. In this instance, current can flow to the semiconductor light emitting device 150 through at least one of the first assembling wiring 321 and the second assembling wiring 322 and the assembling wiring 372, and light with luminance corresponding to the current can be emitted.

Hereinafter, a method of manufacturing the display device 300 according to an embodiment will be described in detail with reference to FIGS. 11 to 21.

FIGS. 11 to 21 are diagrams explaining a method of manufacturing a display device according to an embodiment.

As shown in FIG. 11, the fluid 1200 in which the adhesive particles 381 and 382 are diluted can be accommodated in the chamber 1300. The dilution ratio of adhesive particles 381 and 382 can be optimized. For example, the dilution ratio of fluid 1200 to adhesive particles 381 and 382 can be 10:1 to 7:3, but is not limited thereto.

For example, the substrate 310 can be disposed on the lower portion of the chamber 1300. The substrate 310 can be tightly coupled to the chamber 1300 to prevent the fluid 1200 from leaking out. Although the drawing shows that the substrate 310 is disposed on the lower portion of the chamber 1300, it can also be disposed on the upper portion of the chamber 1300.

For example, after the substrate 310 is fastened to the lower portion of the chamber 1300, the fluid 1200 in which the adhesive particles 381 and 382 are diluted can be accommodated in the chamber 1300. For example, after the substrate 310 is fastened to the lower portion of the chamber 1300, the fluid 1200 can be accommodated in the chamber 1300. Thereafter, the adhesive particles 381 and 382 in powder form can be sprayed into the fluid 1200 and the fluid 1200 can be stirred with a member such as a rotating rod, so that the adhesive particles 381 and 382 can be mixed in the fluid 1200. The adhesion particles 381 and 382 can be randomly distributed in the fluid 1200. The adhesive particles 381 and 382 can move within the fluid 1200 according to the flow of the fluid 1200.

The substrate 310 is a substrate 310 for the display device 300, and a first assembling wiring 321, a second assembling wiring 322, a first insulating layer 330 and a barrier rib 340 having an assembly hole 345 can be disposed on the substrate 310.

Although the drawing shows one assembly hole 345 included in one sub-pixel, in the case of the substrate 310 for the display device 300 for a TV, an assembly hole 345 can be disposed in each of tens of millions to billions of sub-pixels. The semiconductor light emitting devices 150 that generate light of various colors can be disposed in these assembly holes 345, respectively, so that a desired color image can be displayed.

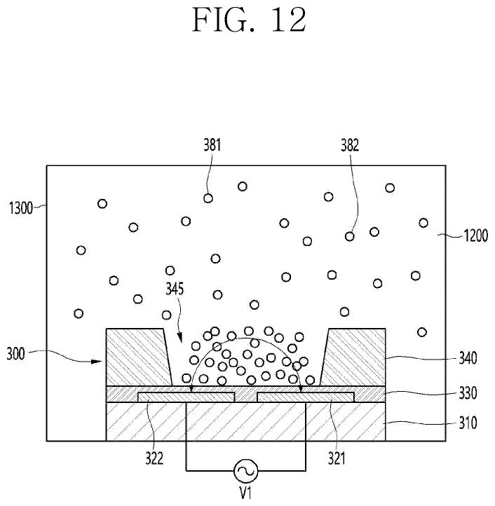

As shown in FIG. 12, a first voltage V1 having a first frequency f1 can be applied to the first assembling wiring 321 and the second assembling wiring 322, and an adhesive part 380 can be formed in the assembly hole 345 using the adhesive particles 381 and 382. The first voltage V1 can be a potential difference applied to the first assembling wiring 321 and the second assembling wiring 322. For example, the first voltage V1 and the ground voltage (0V) can be periodically applied alternately to the first assembling wiring 321 and the second assembling wiring 322 according to the first frequency f1, but is not limited thereto.

A first dielectrophoretic force can be formed by the first voltage V1 having the first frequency f1 applied to the first assembling wiring 321 and the second assembling wiring 322. The adhesive particles 381 and 382 located in the assembly hole 345 and near the assembly hole 345 can be pulled into the assembly hole 345 by the first dielectrophoretic force. The adhesive particles 381 and 382 pulled in this way can accumulate on the bottom part of the assembly hole 345, that is, on the upper surface of the first insulating layer 330.

Therefore, individual control is performed so that the adhesive particles 381 and 382 are attracted inside the assembly hole 345 by using the first dielectrophoretic force formed by the first voltage V1 having the first frequency f1. Therefore, the adhesive particles 381 and 382 can be individually stacked on the bottom part of the assembly hole 345 to form the adhesive part 380 having a stacked structure.

The desired number of adhesive particles 381 and 382 can be set in consideration of the amplitude of the first voltage V1, the intensity of the first frequency f1, the application time of the first voltage V1, etc.

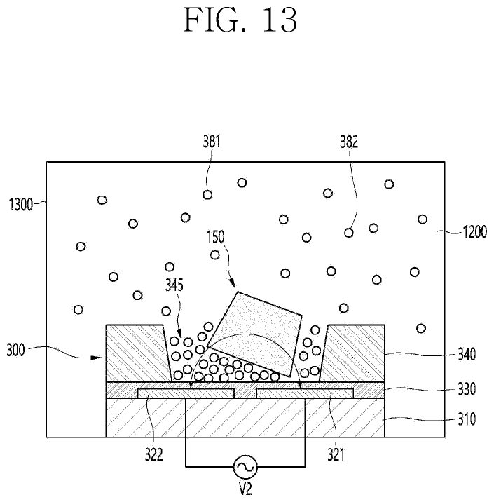

As shown in FIG. 13, when the desired number of adhesive particles 381 and 382 is stacked on the bottom part of the assembly hole 345, the semiconductor light emitting device 150 can be assembled in the assembly hole 345 by applying a second voltage V2 having a second frequency f2 to the first assembling wiring 321 and the second assembling wiring 322. The second voltage V2 can be a potential difference applied to the first assembling wiring 321 and the second assembling wiring 322. For example, the second voltage V2 and the ground voltage (0V) can be periodically applied alternately to the first assembling wiring 321 and the second assembling wiring 322 according to the second frequency f2, but is not limited thereto.

A second dielectrophoretic force can be formed by the second voltage V2 having the second frequency f2 applied to the first assembling wiring 321 and the second assembling wiring 322. The semiconductor light emitting device 150 located near the assembly hole 345 can be pulled into the assembly hole 345 by the second dielectrophoretic force. The semiconductor light emitting device 150 pulled in this way can be positioned on the adhesive particles 381 and 382 stacked in the assembly hole 345.

By continuously applying from the first voltage V1 to the second voltage V2, the semiconductor light emitting device 150 can be pulled into the assembly hole 345 before the adhesive particles 381 and 382 are separated from the assembly hole 345 with the adhesive particles 381 and 382 stacked on the bottom part of the assembly hole 345, so that the adhesive particles 381 and 382 can be stably maintained within the assembly hole 345.

When the adhesive particles 381 and 382 are randomly dispersed in the fluid 1200 and the diameter of the adhesive particles 381 and 382 is very small, it may not be pulled to the bottom part of the assembly hole 345 by the first dielectrophoretic force. Additionally, since the adhesive particles 381 and 382 are randomly dispersed, the adhesive particles 381 and 382 may not be sufficiently located near the assembly hole 345. Therefore, the adhesive particles 381 and 382 that are far from the assembly hole 345 also need to be pulled into the assembly hole 345. For this purpose, the first dielectrophoretic force needs to be large. Accordingly, the first voltage V1 can be greater than the second voltage V2. That is, the first voltage V1 can be equal to or greater than the second voltage V2. For example, the first frequency f1 can be greater than the second frequency f2. That is, the first frequency f1 can be equal to or greater than the second frequency f2.

When the first voltage V1 is greater than the second voltage V2 or the first frequency f1 is greater than the second frequency f2, the first dielectrophoretic force can be large, so that the adhesive particles 381 and 382 that are far from the assembly hole 345 can also be pulled into the assembly hole 345 by the first dielectrophoretic force.

Meanwhile, since the semiconductor light emitting device 150 is heavier than the adhesive particles 381 and 382, a larger second dielectrophoretic force can be required. In order to increase the second dielectrophoretic force, the frequency or voltage must be increased. Accordingly, the second voltage V2 can be greater than the first voltage V1. Additionally, the second frequency f2 can be greater than the first frequency f1.

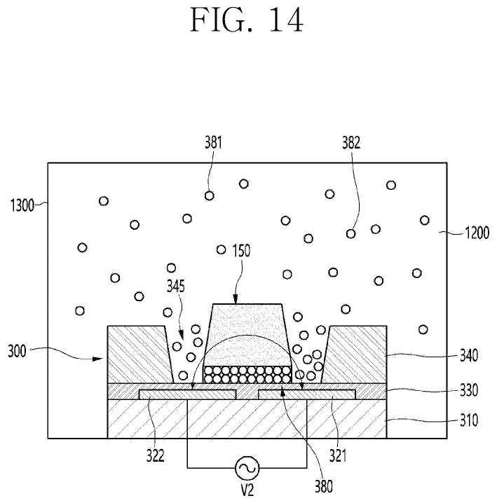

As shown in FIG. 14, the semiconductor light emitting device 150 assembled in the assembly hole 345 can be continuously pressured toward the bottom part of the assembly hole 345 by the second dielectrophoretic force, so that the stacked adhesive particles 381 and 382 located below the semiconductor light emitting device 150 can be aligned so as to be in contact with each other. In particular, since the adhesive particles 381 and 382 have a round shape, the adhesive particles 381 and 382 can collide with each other due to the pressure applied by the semiconductor light emitting device 150, and can be aligned to ensure optimal contact with each other, such as gear alignment. An adhesive part 380 can be formed between the first insulating layer 330 and the semiconductor light emitting device 150 by the adhesive particles 381 and 382 aligned in this way.

As shown in FIG. 15, the substrate 310 can be dried. That is, after exhausting the fluid 1200 from the chamber 1300, the substrate 310 can be detached from the chamber 1300. Thereafter, the substrate 310 can be dried using a heater, etc. to remove the fluid 1200 remaining on the substrate 310 or the semiconductor light emitting device 150.

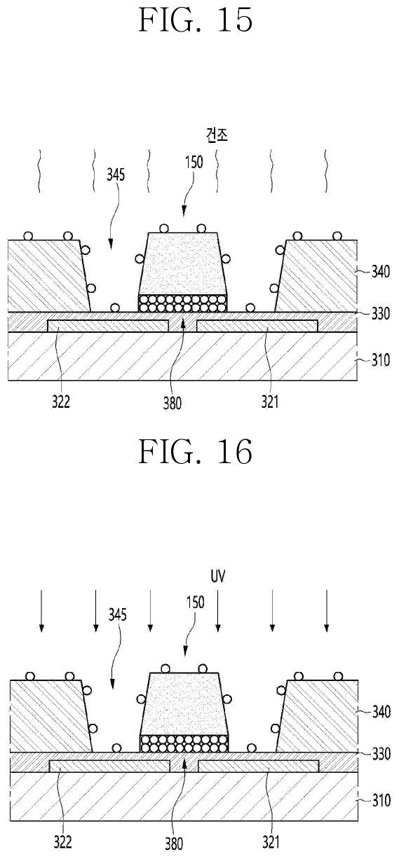

As shown in FIG. 16, the adhesive part 380 can be cured by irradiating ultraviolet light. To this end, the adhesive particles 381 and 382 included in the adhesive part 380 can be made of a photo-curable material. As the adhesive part 380 is hardened, the adhesive properties are strengthened and the semiconductor light emitting device 150 can be firmly attached to the first insulating layer 330 by the adhesive part 380.

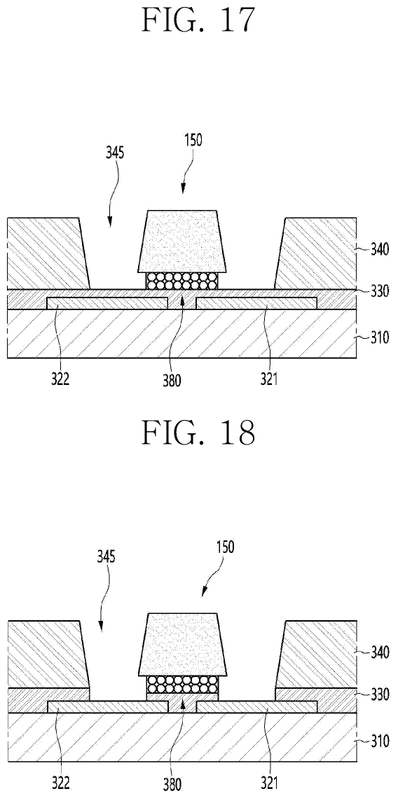

As shown in FIG. 17, the substrate 310 can be cleaned using the fluid 1200. For example, the fluid 1200 can be water such as ultrapure water (DI), but is not limited thereto. For example, a cleaning solution can be mixed with the fluid 1200.

As an example, the substrate 310 can be cleaned by immersing the substrate 310 in a container containing the fluid 1200 for a certain period of time and then lifting the substrate 310.

As another example, the substrate 310 can be cleaned by spraying the fluid 1200 onto the upper surface of the substrate 310.

The adhesive particles 381 and 382 remaining on the substrate 310, the barrier rib 340, the inside of the assembly hole 345, and the semiconductor light emitting device 150 can be removed by the fluid 1200.

The cleaning process can be performed more than once.

For example, a cleaning process (FIG. 17) can be performed first, and then a curing process (FIG. 16) can be performed.

For example, at least one of the drying process (FIG. 15), curing process (FIG. 16), and cleaning process (FIG. 17) can be omitted, but is not limited thereto.

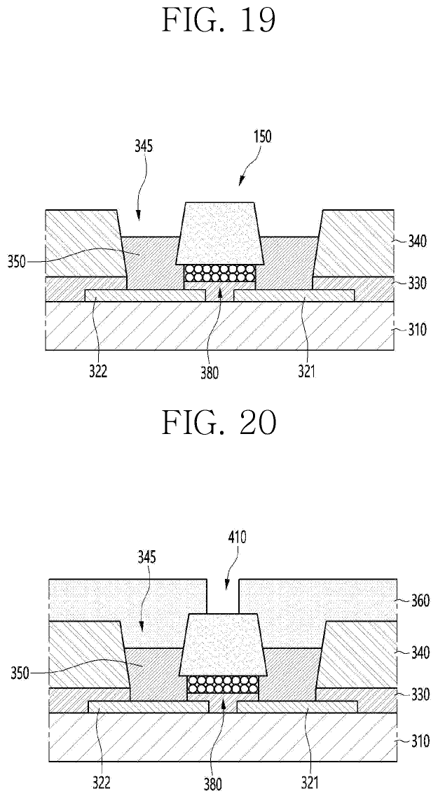

As shown in FIGS. 18 and 19, a process of forming the connection electrode 350 can be performed.

That is, as shown in FIG. 18, the assembly hole 345 can be formed so that the first assembling wiring 321 and/or the second assembling wiring 322 can be exposed for electrical connection with the connection electrode 350. The first insulating layer 330 corresponding between the inner side surface of the assembly hole 345 and the outer side surface of the semiconductor light emitting device 150 can be removed.

For example, when the barrier rib 340 and the first insulating layer 330 are made of the same material, a mask pattern can be formed on the upper surface of the barrier rib 340 to prevent the barrier rib 340 from being etched by the etchant for etching the first insulating layer 330. For example, the mask pattern can be formed on the inner side surface of the barrier rib 340, that is, on the inner side surface of the assembly hole 345, but is not limited thereto.

For example, if the barrier rib 340 is not etched by an etchant for etching the first insulating layer 330, the mask pattern may not be formed.

In this instance, the barrier rib 340, the semiconductor light emitting device 150, and/or the adhesive part 380 can act as a mask. That is, the etchant can be in contact with the first insulating layer 330 within the assembly hole 345 between the inner side surface of the assembly hole 345 and the outer side surface of the semiconductor light emitting device 150 and/or the side portion of the adhesive part 380, so that the first insulating layer 330 can be etched by an etchant. Etching of the first insulating layer 330 can be performed until the first assembling wiring 321 and/or the second assembling wiring 322 are exposed.

As shown in FIG. 19, after depositing a metal film on the substrate 310 using a deposition process, a patterning process can be performed to form the connection electrode 350 within the assembly hole 345. The connection electrode 350 can be electrically connected to the side portion of the semiconductor light emitting device 150, that is, to the side portion of the first electrode 154 of the semiconductor light emitting device 150 and the first assembling wiring 321 and/or the second assembling wiring 322. At this time, the first assembling wiring 321 and/or the second assembling wiring 322 can be used as an electrode wiring for supplying voltage to the semiconductor light emitting device 150. Accordingly, the first assembling wiring 321 and/or the second assembling wiring 322 can be used not only to form the adhesive part 380 and forming a dielectrophoretic force for assembling the semiconductor light emitting device 150 but also as the electrode wiring for supplying voltage to the semiconductor light emitting device 150.

As shown in FIG. 20, a second insulating layer 360 can be formed on the substrate 310, and a patterning process can be performed to form a contact hole 410 on the upper portion of the semiconductor light emitting device 150. That is, the contact hole 410 can be formed by removing the second insulating layer 360 corresponding to a part of the upper portion of the semiconductor light emitting device 150.

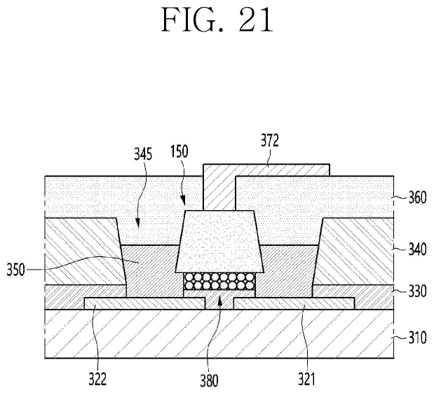

As shown in FIG. 21, an electrode wiring 372 can be electrically connected to the upper portion of the semiconductor light emitting device 150, that is, to the second electrode 155 of the semiconductor light emitting device 150, through the contact hole 410. For example, a metal film can be formed on the second insulating layer 360, and a patterning process can be performed to form an electrode wiring 372 that is electrically connected to the upper portion of the semiconductor light emitting device 150 through the contact hole 410.

The above detailed description should not be construed as restrictive in any respect and should be considered illustrative. The scope of the embodiments should be determined by reasonable interpretation of the appended claims, and all changes within the equivalent scope of the embodiments are included in the scope of the embodiments.

The embodiment can be adopted in the display field for displaying images or information.

The embodiment can be adopted in the display field for displaying images or information using a semiconductor light emitting device. The semiconductor light emitting device can be a micro-level semiconductor light emitting device or a nano-level semiconductor light emitting device.

1. A display device, comprising:
a substrate;
a barrier rib disposed on the substrate and having an assembly hole;
a semiconductor light emitting device in the assembly hole;
a connection electrode within the assembly hole; and
an adhesive part between the substrate and the semiconductor light emitting device within the assembly hole,
wherein the adhesive part comprises adhesive particles in contact with each other, and
wherein the connection electrode is in contact with the adhesive particles along a circumference of a side portion of the adhesive part.

2. The display device of claim 1, wherein the adhesive particles in contact with each other are stacked in at least two directions.

3. The display device of claim 1, wherein the adhesive part comprises a plurality of layers.

4. The display device of claim 3, wherein the adhesive part comprises:
a first adhesive layer comprising a plurality of first adhesive particles; and
a second adhesive layer stacked on the first adhesive layer and comprising a plurality of second adhesive particles.

5. The display device of claim 4, wherein the plurality of first adhesive particles are in contact with each other along a horizontal direction, and the plurality of second adhesive particles are in contact with each other along the horizontal direction.

6. The display device of claim 4, wherein the plurality of first adhesive particles each overlap other along a horizontal direction, and the plurality of second adhesive particles each overlap other along the horizontal direction.

7. The display device of claim 4, wherein the plurality of first adhesive particles are in contact with each other along a vertical direction, and the plurality of second adhesive particles are in contact with each other along the vertical direction.

8. The display device of claim 4, wherein the plurality of first adhesive particles each overlap other along a vertical direction, and the plurality of second adhesive particles each overlap other along the vertical direction.

9. The display device of claim 4, wherein the plurality of first adhesive particles are in contact with each other along a diagonal direction, and the plurality of second adhesive particles are in contact with each other along the diagonal direction.

10. The display device of claim 4, wherein the plurality of first adhesive particles each overlap other along a diagonal direction, and the plurality of second adhesive particles each overlap other along the diagonal direction.

11. The display device of claim 1, wherein a width of the adhesive part is smaller than a diameter of the semiconductor light emitting device.

12. The display device of claim 1, wherein a thickness of the adhesive part is 10 nm to 1 μm.

13. The display device of claim 1, wherein the adhesive part is one of an organic material, a photo-curable material, and a dielectric material.

14. The display device of claim 1, comprising:
a first assembling wiring on the substrate;
a second assembling wiring on the substrate; and
a first insulating layer on the first assembling wiring and the second assembling wiring,
wherein the adhesive part is disposed between the first insulating layer and the semiconductor light emitting device within the assembly hole.

15. The display device of claim 14, comprising:
a second insulating layer on the barrier rib and the semiconductor light emitting device; and
an electrode wiring configured to be connected to the semiconductor light emitting device through the second insulating layer,
wherein the connection electrode is configured to connect at least one of the first assembling wiring and the second assembling wiring to a side portion of the semiconductor light emitting device.

16. (canceled)

17. A method of manufacturing a display device comprising a substrate, first and second assembling wirings on the substrate, and an assembly hole on the substrate, comprising:
providing a chamber containing a fluid in which adhesive particles are diluted;
forming an adhesive part in the assembly hole by using the adhesive particles by applying a first voltage having a first frequency to the first assembling wiring and the second assembling wiring; and
assembling a semiconductor light emitting device into the assembly hole by applying a second voltage having a second frequency to the first assembling wiring and the second assembling wiring,
wherein the first voltage is greater than the second voltage.

18. The method of manufacturing a display device of claim 17, comprising:
curing the adhesive part by irradiating ultraviolet light; and
cleaning the substrate.

19. (canceled)

20. The method of manufacturing a display device of claim 17, wherein the first frequency is greater than the second frequency.
